(19) United States
(12) Patent Application Publication
(10) Pub. No.: US 2026/0371671 A1
(43) Pub. Date: Nov. 19, 2026

(54) INTEGRATED CIRCUIT WITH NANOSTRUCTURE TRANSISTORS AND FLEXIBLE BOTTOM SOURCE/DRAIN EPITAXY FOR DEVICE PERFORMANCE

(71) Applicant: Taiwan Semiconductor Manufacturing Co., Ltd., Hsinchu (TW)

(72) Inventors: Tsung-Han CHUANG, Hsinchu (TW); Jung-Hung CHANG, Hsinchu (TW); Shih-Cheng CHEN, Hsinchu (TW); Wen-Ting LAN, Hsinchu (TW); Fu-Cheng CHANG, Hsinchu (TW); Chia-Cheng TSAI, Hsinchu (TW); Kuo-Cheng CHIANG, Hsinchu (TW)

(73) Assignee: Taiwan Semiconductor Manufacturing Co., Ltd., Hsinchu (TW)

(21) Appl. No.: 19/755,524

(22) Filed: Jul. 27, 2026

Related U.S. Application Data
(63) Continuation of application No. 18/655,086, filed on May 3, 2024.

(51) Int. Cl. H10D 62/13; H10D 30/01; H10D 30/43; H10D 30/67; H10D 62/10; H10D 84/01; H10D 84/03; H10D 84/85

(52) U.S. Cl. CPC H10D 62/151; H10D 30/014; H10D 30/43; H10D 30/6735; H10D 62/121; H10D 84/017; H10D 84/0188; H10D 84/038; H10D 84/85

(57) ABSTRACT

An integrated circuit includes a semiconductor substrate, a first recess in the semiconductor substrate, and a transistor. The transistor includes a plurality of stacked channels. A bottom of the recess is lower than all of the channels. The transistor includes a source/drain region including a bottom epitaxial structure in the recess. The bottom epitaxial structure includes a first semiconductor layer in contact with the bottom of the first recess and has a top surface lower than all of the channels and a semiconductor material different than the semiconductor substrate. The source/drain region includes a second semiconductor layer having a bottom surface on the bottom epitaxial structure lower than all of the channels and a top surface higher than all of the channels.

### BACKGROUND

There has been a continuous demand for increasing computing power in electronic devices including smart phones, tablets, desktop computers, laptop computers and many other kinds of electronic devices. Integrated circuits provide the computing power for these electronic devices. One way to increase computing power in integrated circuits is to increase the number of transistors and other integrated circuit features that can be included for a given area of semiconductor substrate.

Nanostructure transistors can assist in increasing computing power because the nanostructure transistors can be very small and can have improved functionality over conventional transistors. A nanostructure transistor may include a plurality of semiconductor nanostructures (e.g., nanowires, nanosheets, etc.) that act as the channel regions for a transistor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of an integrated circuit, in accordance with some embodiments.

FIGS. 2A-2I are cross-sectional views of an integrated circuit at various stages of processing, in accordance with some embodiments.

FIGS. 3A-3E are cross-sectional views of an integrated circuit at various stages of processing, in accordance with some embodiments.

FIGS. 4A-4E are cross-sectional views of an integrated circuit at various stages of processing, in accordance with some embodiments.

FIG. 5 is a flow diagram of a process for forming an integrated circuit, in accordance with some embodiments.

### DETAILED DESCRIPTION

In the following description, many thicknesses and materials are described for various layers and structures within an integrated circuit die. Specific dimensions and materials are given by way of example for various embodiments. Those of skill in the art will recognize, in light of the present disclosure, that other dimensions and materials can be used in many cases without departing from the scope of the present disclosure.

The following disclosure provides many different embodiments, or examples, for implementing different features of the described subject matter. Specific examples of components and arrangements are described below to simplify the present description. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the following description, certain specific details are set forth in order to provide a thorough understanding of various embodiments of the disclosure. However, one skilled in the art will understand that the disclosure may be practiced without these specific details. In other instances, well-known structures associated with electronic components and fabrication techniques have not been described in detail to avoid unnecessarily obscuring the descriptions of the embodiments of the present disclosure.

Unless the context requires otherwise, throughout the specification and claims that follow, the word “comprise” and variations thereof, such as “comprises” and “comprising,” are to be construed in an open, inclusive sense, that is, as “including, but not limited to.”

The use of ordinals such as first, second and third does not necessarily imply a ranked sense of order, but rather may only distinguish between multiple instances of an act or structure.

Reference throughout this specification to “one embodiment” or “an embodiment” means that a particular feature, structure or characteristic described in connection with the embodiment is included in at least some embodiments. Thus, the appearances of the phrases “in one embodiment”, “in an embodiment”, or “in some embodiments” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise.

Embodiments of the present disclosure provide an integrated circuit with nanostructure transistors. Each nanostructure transistor includes a plurality of stacked channels. The stacked channels extend between source/drain regions. Embodiments of the present disclosure provide source/drain regions with bottom epitaxial structures extending lower than a lowest channel. The bottom epitaxial structures include semiconductor materials with different compositions than other higher portions of the source/drain regions. Furthermore, N-channel transistors and P-channel transistors may have different types of bottom epitaxial structures with different numbers of layers and different shapes of layers. The result is that stress or strain can be imparted to the source/drain regions and channels in a manner selected to improve DC performance of the transistors. This results in transistors with improved characteristics, integrated circuits with improved characteristics, and electronic devices with improved characteristics. Furthermore, the function and reliability of transistors is improved in such a way that wafer yields are improved, resulting in fewer scrapped wafers.

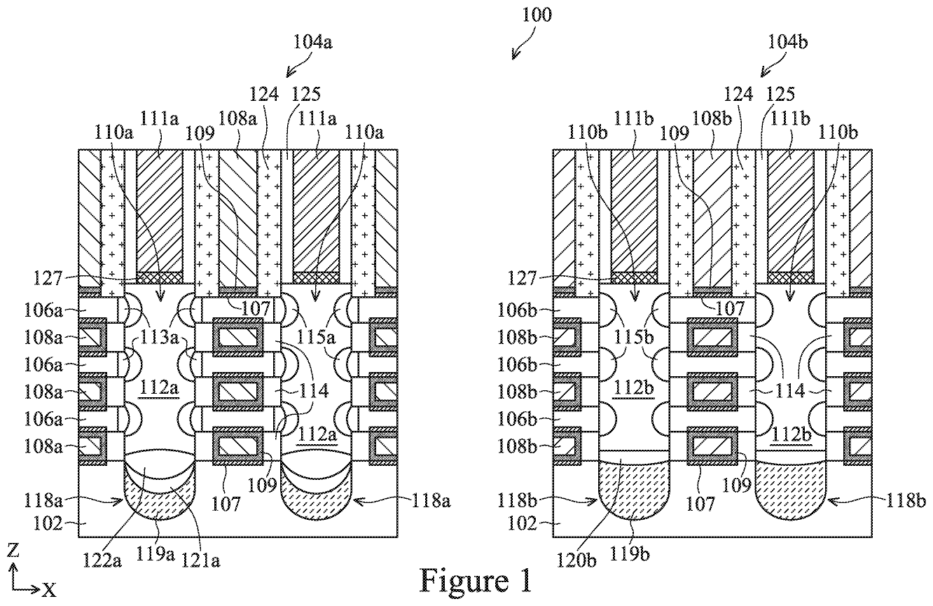

FIG. 1 is a cross-sectional view of an integrated circuit 100, in accordance with some embodiments. The integrated circuit 100 includes a substrate 102. The integrated circuit also includes two transistors 104a and 104b. As will be set forth in more detail below, the transistors 104a and 104b include bottom source/drain epitaxial structures with compositions and characteristics selected to improve the performance of the transistors.

The Figures include some reference numbers having suffixes “a” or “b”. For example, transistors 104a and 104b, channels 106a and 106b (described below), and gate metals 108a and 108b, and others. In some cases, the description below may omit the suffix “a” or “b” when reference is not made to a particular structure. For example, the transistors 104a and 104b may collectively be referred to as transistor 104 in some cases.

The transistors 104a and 104b may correspond to gate all around transistors. The gate all around transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the gate all around structure. Furthermore, the gate all around transistors 104a and 104b may each include a plurality of semiconductor nanostructures corresponding to channel regions of the transistors 104a and 104b. The nanostructures may include nanosheets, nanowires, or other types of nanostructures.

In some embodiments, the substrate 102 includes a single crystalline semiconductor layer on at least a surface portion. The substrate 102 may include a single crystalline semiconductor material such as, but not limited to Si, Ge, SiGe, GaAs, InSb, GaP, GaSb, InAlAs, InGaAs, GaSbP, GaAsSb and InP. In an example process described herein, the substrate 102 includes Si, though other semiconductor materials can be utilized without departing from the scope of the present disclosure.

The transistors 104 each include a plurality of channels 106. The channels 106 are stacked in the vertical direction or Z direction. In the example of FIG. 1, there are three stacked channels 106 for each transistor 104. However, in practice, there may be only two stacked channels 106 or there may be more than three stacked channels 106 without departing from the scope of the present disclosure. The channels 106 correspond to channel regions of the transistor 104. More particularly, transistor 104a includes three channels 106a and the transistor 104b includes three channels 106b.

The channels 106 may include one or more layers of Si, SiGe, or other semiconductor materials. Other semiconductor materials can be utilized for the channels 106 without departing from the scope of the present disclosure. In a non-limiting example described herein, the channels 106 are silicon. The vertical thickness of the channels 106 can be between 3 nm and 10 nm. The semiconductor channels 106 may be separated from each other by 3 nm to 15 nm. Other thicknesses and materials can be utilized for the channels 106 without departing from the scope of the present disclosure.

The transistors 104 each include a gate metal 108. The gate metal 108 surrounds the channels 106. The gate metal 108 corresponds to a gate electrode, or may correspond to one of the metals that make up a gate electrode of the transistor 108. The gate metal 108 can include one or more of titanium nitride, tungsten, tantalum, tantalum nitride, tantalum aluminum nitride, ruthenium, cobalt, aluminum, titanium, or other suitable conductive materials. The gate metal 108 may have a length in the X direction between 5 nm and 150 nm. Other materials and thicknesses can be utilized for the gate metal 108 without departing from the scope of the present disclosure. In some embodiments, the gate metal 108a of the transistor 104a includes a different material or different layers than the gate metal 108b of the transistor 104b. The difference in composition or materials may be selected to impart a desired work function to the different transistors 104a and 104b.

The transistor 104a includes source/drain regions 110a. The source/drain regions 110a are both in contact with each of the channels 106a. Each channel 106a extends in the X direction between the source/drain regions 110a. The source/drain regions 110a include one or more semiconductor materials. The source/drain regions 110a can be doped with P-type dopants species, such as boron or other P-type dopants. As will be set forth in more detail below, the source/drain regions 110a of the transistor 104a includes a plurality of different semiconductor materials.

In some embodiments, the source/drain regions 110a of the transistor 104a include a source/drain bottom epitaxial structure 118a. The bottom epitaxial structure 118a is formed in a concave recess or trench in the substrate 102. The concave recess extends below a lowest channel 106a and below a lowest portion of the gate metal 108a. The bottom epitaxial structure 118a includes one or more semiconductor materials. The semiconductor materials may be grown epitaxially from the substrate, initially. The different material of the bottom epitaxial structure can assist in imparting a beneficial strain to the source/drain regions 110a and to the channels 106a.

In some embodiments, the bottom epitaxial structure 118a includes an epitaxial semiconductor layer 119a. The epitaxial semiconductor layer 119a is in direct contact with the substrate 102. The first epitaxial semiconductor layer 119a is epitaxially grown from the substrate 102. The semiconductor layer 119a has a bottom surface in the shape of the recess in the substrate 102. The semiconductor layer 119a has a top surface with a concave shape.

In some embodiments, the substrate 102 includes silicon and the epitaxial semiconductor layer 119a includes silicon germanium, including a concentration of germanium between 25% and 35%, though other concentrations can be utilized without departing from the scope of the present disclosure. In some embodiments, the first epitaxial semiconductor layer 119a is doped with P-type dopant atoms in situ during the epitaxial growth process. The P-type dopant atoms can include boron or other dopant species.

In some embodiments, the bottom epitaxial structure 118a includes an epitaxial semiconductor layer 121a. The epitaxial semiconductor layer 121a is in direct contact with the epitaxial semiconductor layer 119a and of a portion of the substrate 102 above the epitaxial semiconductor layer 118a. The second epitaxial semiconductor layer 121a is epitaxially grown from the semiconductor layer 119a. The semiconductor layer 121a has a bottom surface in the shape of the recess in the substrate 102. The semiconductor layer 121a has a top surface with a concave shape.

In some embodiments, the epitaxial semiconductor layer 121a includes a different semiconductor material than the semiconductor layer 119a in the same semiconductor material as the substrate 102. In an example in which the substrate 102 includes silicon and the semiconductor layer 119a includes silicon germanium, the semiconductor layer 121a includes silicon. The difference in crystalline structure of the semiconductor layer 121a can assist in imparting a beneficial strain or stress to the source/drain region 110a and to the channels 106a. In some embodiments, the epitaxial semiconductor layer 121a is doped with P-type dopant atoms in situ during the epitaxial growth process. The P-type dopant atoms can include boron or other dopant species.

In some embodiments, the bottom epitaxial structure 118a includes an epitaxial semiconductor layer 122a. The epitaxial semiconductor layer 122a is on the epitaxial semiconductor layer 121a. The epitaxial semiconductor layer 122a may contact a portion of the lowest inner spacers 114 (to be described further below). In some embodiments, the top surface of the epitaxial semiconductor layer 122a is convex in that the central portion is higher than a lateral end portions.

In some embodiments, the semiconductor layer 122a includes a different semiconductor material than the semiconductor layer 121a. In an example in which the layer 119a includes silicon germanium and the layer 121a include silicon, the semiconductor layer 122a include silicon germanium. In some embodiments, the semiconductor layer 121a can include SiB (silicon doped with boron). The concentration of germanium of the semiconductor layer 122a is less than 25%, though other concentrations can be utilized without departing from the scope of the present disclosure. The mismatch in semiconductor materials can assist in imparting a beneficial strain or stress to the channel region 110a and to the channels 106a. The semiconductor layer 122a can be doped with P-type dopant atoms, such as boron, or other suitable dopant species. More particularly, each semiconductor material may include a crystalline structure having particular distances between atoms of the crystalline structure. When two different semiconductor materials interface with each other at boundary, the mismatch in the spacing between atoms may result in a compressive or tensile strain. Such strain can result in beneficial improvements in electron or hole mobility.

In some embodiments, the source/drain regions 110a include epitaxial semiconductor layers 113a are in direct contact with the channels 106a. Accordingly, the semiconductor layers 113a can be grown epitaxially from the channels 106a. In some embodiments, the epitaxial semiconductor layers 113a are grown in a same epitaxial growth process as the semiconductor layer 121a. Accordingly, the semiconductor layers 113a can include silicon doped in situ with P-type dopant atoms, though other materials and processes can be utilized without departing from the scope of the present disclosure.

In some embodiments, the source/drain regions 110a include epitaxial semiconductor layers 115a in direct contact with the layers 113a. Accordingly, the epitaxial semiconductor layers 115a can be grown epitaxially from the epitaxial semiconductor layers 113a. In some embodiments, the epitaxial semiconductor layers 115a are grown in a same epitaxial growth process as the semiconductor layer 122a. Accordingly, the semiconductor layers 115a can include silicon germanium with a concentration of germanium less than 25% and doped in situ with P-type dopant atoms, though other materials and processes can be utilized without departing from the scope of the present disclosure. The source/drain layers 115a each protrude in a convex manner.

The source/drain regions 110a can include a semiconductor layer 112a. The semiconductor layer 112a corresponds to a bulk source/drain region that fills the remaining areas of the source/drain trenches and gross to a height above the highest channel 106 a. The semiconductor layer 112a includes a different semiconductor material than the source/drain layers 115a and 122a. In an example in which the semiconductor layers 115a and 122a include silicon germanium with a germanium concentration less than 25%, the semiconductor layer 112a can include silicon germanium with a concentration greater than 25% and doped in situ with P-type dopant species. Other processes and materials can be utilized without departing from the scope of the present disclosure.

While the source/drain regions 110a of the transistor 104a are shown with a particular set of semiconductor layers in FIG. 1, in practice, the source/drain regions 110a can have other structures and compositions without departing from the scope of the present disclosure. For example, some embodiments described further below illustrate processes that results in different structures for the source/drain regions 110a than are shown in FIG. 1. These other structures for the source/drain regions 110a can be utilized for a transistor 104a of FIG. 1 without departing from the scope of the present disclosure. In some embodiments, the source/drain regions 110a include silicon germanium. The silicon germanium can have a concentration of germanium between 25% and 35%, though other materials and concentrations can be utilized without departing from the scope of the present disclosure.

The transistor 104b includes source/drain regions 110b. The source/drain regions 110b are both in contact with each of the channels 106b. Each channel 106b extends between the source/drain regions 110b. The source/drain regions 110b include one or more semiconductor materials. The source/drain regions 110b can be doped with N-type dopants species, such as phosphorus, arsenic, or other N-type dopants. As will be set forth in more detail below, the source/drain regions 110b of the transistor 104b may include a plurality of different semiconductor materials.

In some embodiments, the source/drain regions 110b of the transistor 104b include a bottom epitaxial structure 118b the bottom epitaxial structure 118b is formed in a concave recess in the substrate 102. The concave recess extends below a lowest channel 106b and below a lowest portion of the gate metal 108b. The bottom epitaxial structure 118b includes one or more semiconductor materials. The semiconductor materials may be grown epitaxially from the substrate, initially. The different material of the bottom epitaxial structure can assist in imparting a beneficial strain to the source/drain regions 110b and to the channels 106b.

In some embodiments, the bottom epitaxial structure 118b includes an epitaxial semiconductor layer 119b. The epitaxial semiconductor layer 119b is in direct contact with the substrate 102. Indeed, the first epitaxial semiconductor layer 119b is epitaxially grown from the substrate 102. The semiconductor layer 119b has a bottom surface in the shape of the recess in the substrate 102. The semiconductor layer 119b has a substantially flat top surface, or a mildly concave top surface.

In some embodiments, the substrate 102 includes silicon and the epitaxial semiconductor layer 119b includes silicon germanium, including a concentration of germanium between 25% and 35%, though other concentrations can be utilized without departing from the scope of the present disclosure. In some embodiments, the first epitaxial semiconductor layer 119b has an identical composition with the semiconductor layer 119b and may be formed in a same epitaxial growth process.

In some embodiments, the source/drain regions 110b include dielectric isolation structures 120b on a top surface of the source/drain epitaxial structure 118b. The dielectric isolation structures 120b can be positioned lower than a lowest channel 106b of the transistor 104b.

In some embodiments, the dielectric isolation structures 120b may include SiN, SiON, SiOCN, SiOC, SiCN, SiO, AlO, HfO, or other suitable dielectric materials. The dielectric isolation structure 120b may have a thickness between 1 nm and 15 nm. This thickness may be sufficiently thick to ensure substantially no leakage current, but not so thick as to adversely affect the potential thickness of a source/drain region that will be formed thereon. Other thicknesses and materials can be utilized for the dielectric isolation structures 120b without departing from the present disclosure.

The presence of the dielectric isolation structures 120b ensures that leakage currents will not flow from the source/drain regions 110b into the semiconductor substrate 102. This can greatly enhance the efficiency of the transistor 104b by substantially eliminating leakage currents. This reduces power consumption and heat generation. Although not shown, in some embodiments the transistors 104a may also include dielectric isolation structures, although such structures may be less beneficial for p-type transistors than for n-type transistors.

In some embodiments, the source/drain regions 110b include epitaxial semiconductor layers 115b in direct contact with the channels 106b. Accordingly, the semiconductor layers 115b can be grown epitaxially from the channels 106b. The semiconductor layers 115a can include silicon doped in situ with N-type dopant atoms, though other materials and processes can be utilized without departing from the scope of the present disclosure. In some embodiments, the semiconductor layers 115b can be doped with arsenic or phosphorus. The semiconductor layers 115b protrude complexly from the channels 106b.

The source/drain regions 110b can include a semiconductor layer 112b. The semiconductor layer 112b corresponds to a bulk source/drain region that fills the remaining areas of the source/drain trenches and gross to a height above the highest channel 106b. In some embodiments, the semiconductor layer 112b include silicon doped with N-type dopants species. In one example, the semiconductor layer 112b is doped with phosphorus, while the semiconductor layer 115b is doped with arsenic.

The transistors 104 includes a gate dielectric made up of an interfacial dielectric layer 107 and the high K dielectric layer 109. The gate dielectric is positioned between the gate metal 108 and the channels 106. The gate dielectric surrounds the channels 106. The gate metal 108 surrounds the gate dielectric.

The interfacial gate dielectric layer 107 is a low-K gate dielectric layer. The interfacial gate dielectric layer 107 is in contact with the channels 106. The high-K gate dielectric layer 109 is in contact with the low-K gate dielectric layer 107 and the gate metal 108. The interfacial gate dielectric layer 107 is positioned between the channels 106 and the high-K gate dielectric layer 109.

The interfacial gate dielectric layer 107 can include a dielectric material such as silicon oxide, silicon nitride, or other suitable dielectric materials. The interfacial dielectric layer 107 can include a comparatively low-K dielectric with respect to high-K dielectric such as hafnium oxide or other high-K dielectric materials that may be used in gate dielectrics of transistors.

The high-K gate dielectric layer 109 includes one or more layers of a dielectric material, such as HfO2, HfSiO, HfSiON, HfTaO, HfTiO, HfZrO, zirconium oxide, aluminum oxide, titanium oxide, hafnium dioxide-alumina (HfO2—Al2O3) alloy, other suitable high-k dielectric materials, and/or combinations thereof. The thickness of the high-k dielectric 109 is in a range from about 1 nm to about 3 nm. Other thicknesses, deposition processes, and materials can be utilized for the high-K gate dielectric layer 109 without departing from the scope of the present disclosure. The high-K gate dielectric layer 109 may include a first layer that includes HfO2 with dipole doping including La and Mg, and a second layer including a higher-K ZrO layer with crystallization.

The transistors 104 includes inner spacers 114. The inner spacers 114 can include silicon oxide, silicon oxynitride, silicon carbonitride, silicon oxycarbonitride, fluorine-doped silicate glass (FSG), a low-K dielectric material or other dielectric materials without departing from the scope of the present disclosure. The inner spacers 114 physically separate the gate metal 108a from the source/drain regions 110. This prevents short circuits between the gate metal 108a and the source/drain regions 110. The inner spacers 114 may have a thickness between 2 nm and 10 nm. Other materials, dimensions, and structures can be utilized for the inner spacers 114 without departing from the scope of the present disclosure. The inner spacers 114 may have a thickness between 2 nm and 10 nm.

The transistor 104 includes source/drain contacts 111. Each source/drain contact 111 is positioned over and electrically connected to a respective source/drain region 110. Electrical signals may be applied to the source/drain regions 110 via the source/drain contacts 111. The source/drain contacts 111 can include a conductive material such as tungsten, cobalt, ruthenium, titanium, aluminum, tantalum, or other suitable conductive materials. The source/drain contacts may have a width between 5 nm and 50 nm.

The transistors 104 may include silicide 127. The silicide 127 is formed at the top of the source/drain regions 110. The source/drain contacts 111 are positioned in contact with the silicide. The silicide promotes good electrical connection between the source/drain contacts 111 and the source/drain regions 110. The silicide can include titanium silicide, aluminum silicide, nickel silicide, tungsten silicide, or other suitable silicides. The source/drain contacts 111 may have a width between 5 nm and 50 nm.

The transistors 104 include a pair of dielectric layers 124 and 125. The dielectric layers 124 and 125 may collectively function as gate spacer layers positioned between the gate electrode 108 and the source/drain contact 111. The dielectric layer 124 may correspond to a contact etch stop layer and may be positioned in contact with the gate metal 108. The dielectric layer 124 may include SiN, SiON, SiOCN, SiCN, or other suitable dielectric materials. The dielectric layer 125 may correspond to a gate spacer layer and may include silicon oxide or another suitable dielectric material.

The transistors 104 can be operated by applying voltages to the source/drain regions 110a and the gate metal 108. The voltages can be applied to the source/drain regions 110 via the source/drain contacts 111. The voltages can be applied to the gate metal 108 via a gate contact not shown in FIG. 1. The voltages can be selected to turn on the transistor 104 or to turn off the transistor 104. When the transistor 104 is turned on, currents may flow between the source/drain regions 110 through each of the channels 106. When the substrate 102 is turned off, currents do not flow through the channels 106.

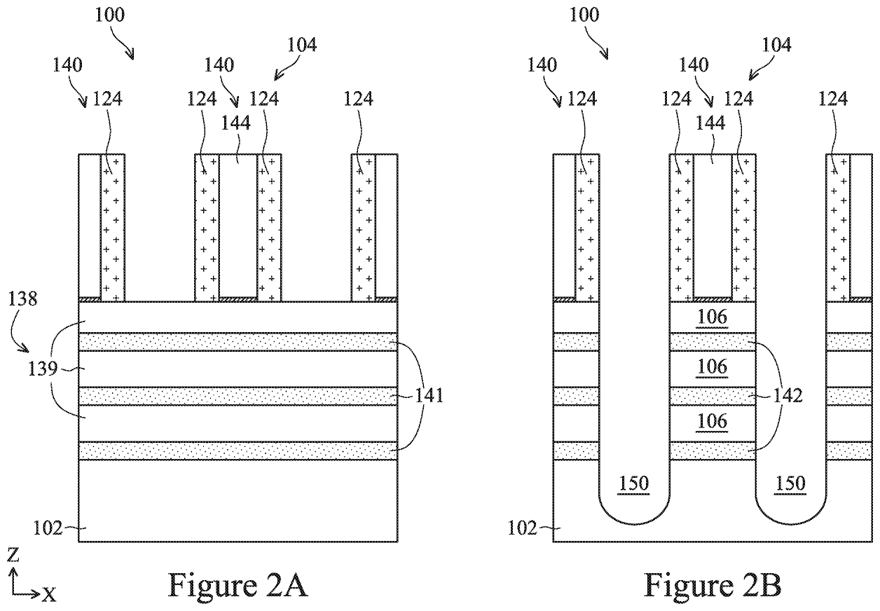

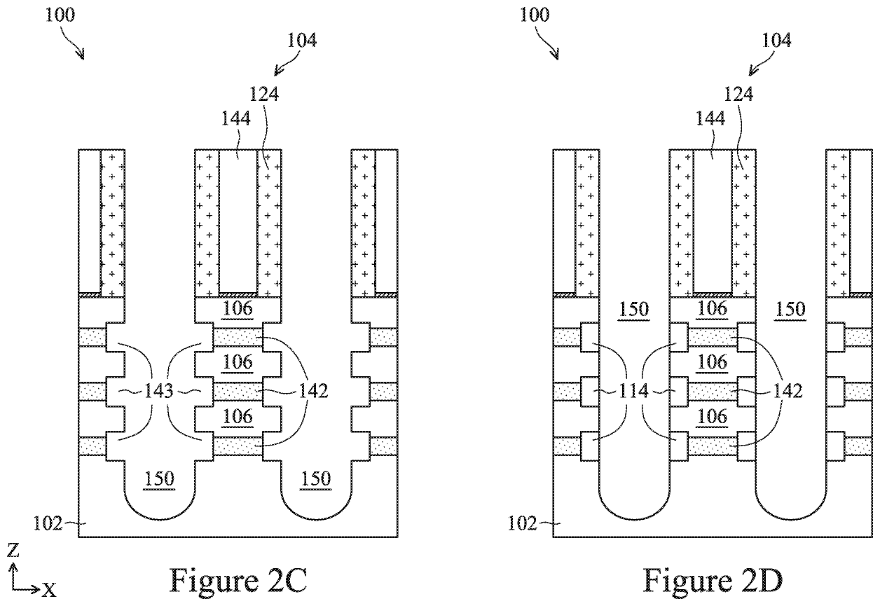

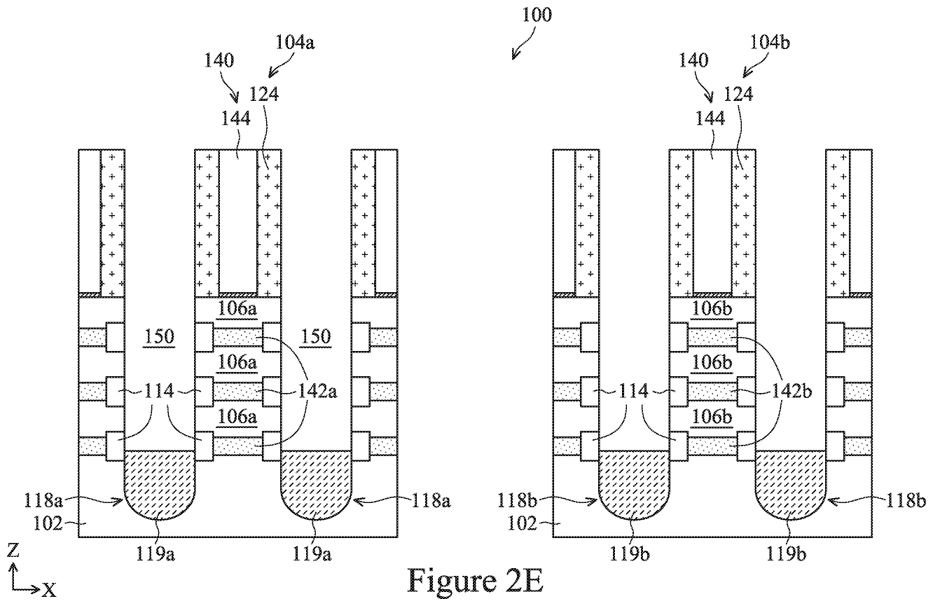

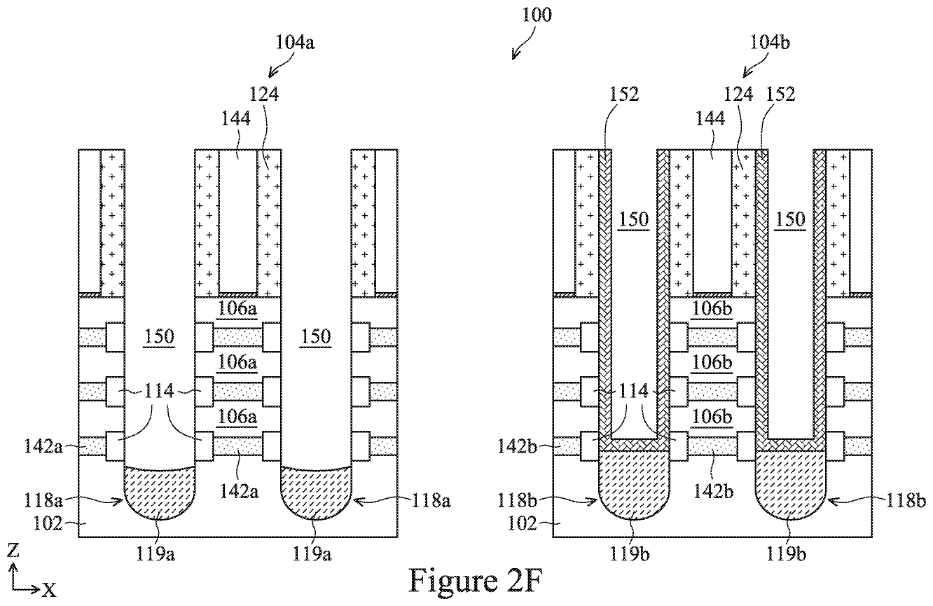

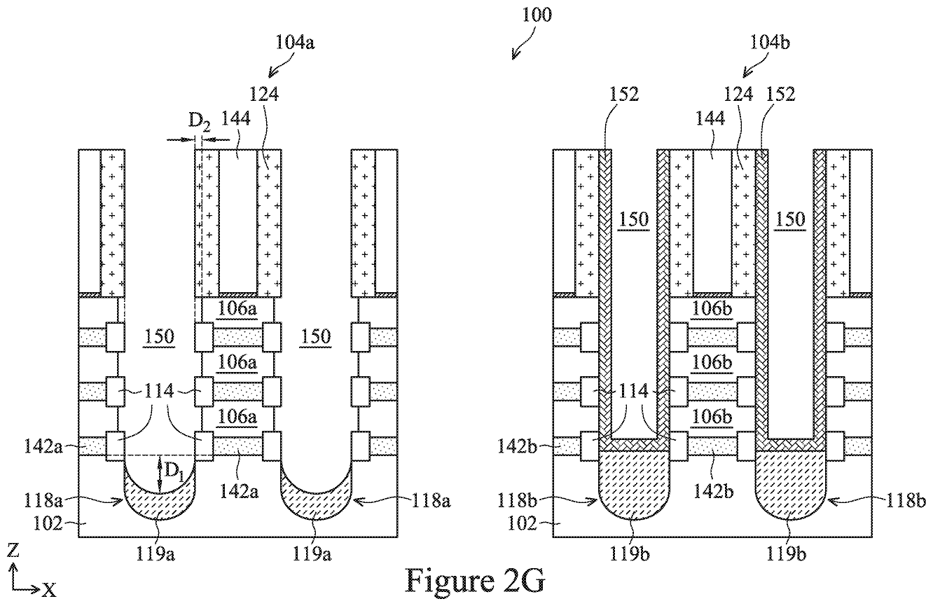

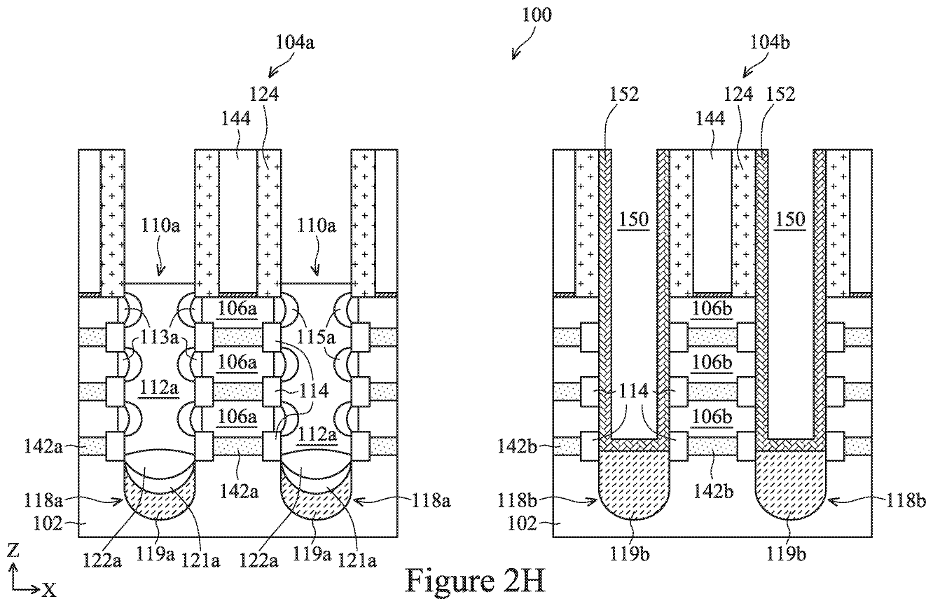

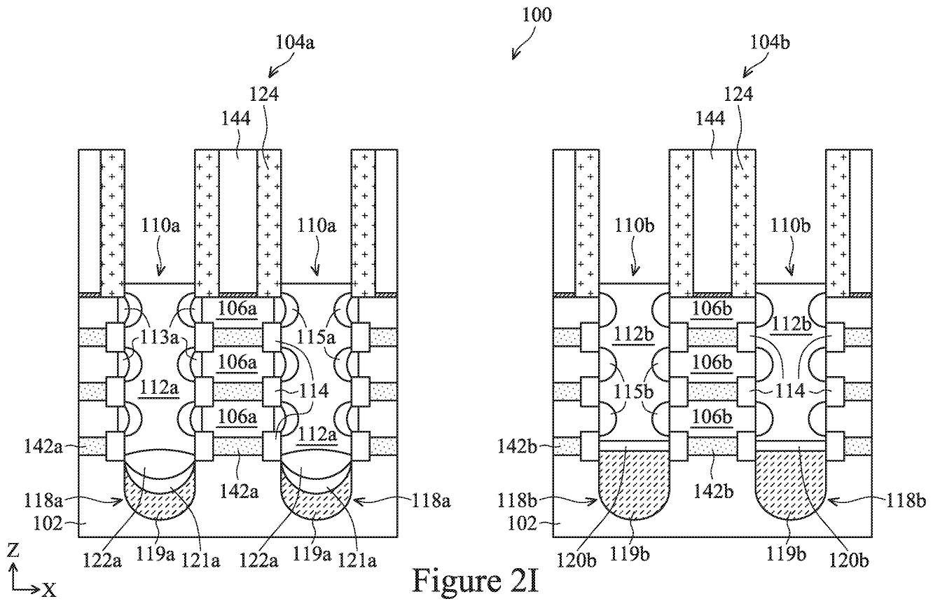

FIGS. 2A-2I are cross-sectional views of an integrated circuit 100 at various stages of processing for forming transistors 104, in accordance with some embodiments. FIGS. 2A-2D do not separately illustrated a region for a P-type transistor and the region of an N-type transistor. The process steps shown in FIGS. 2A-2D can be utilized in formation of both the P-type transistors and the N-type transistors. FIGS. 2E-2I each illustrate separate locations of P-type and N-type transistors.

In FIG. 2A, a stack 138 of semiconductor layers has been formed on the substrate 102. Though not apparent in the view of FIG. 2A, the stack 130 of semiconductor layers may be patterned in fins extending in the X direction. A plurality of transistors 104 may be formed in each fin.

The semiconductor stack includes a plurality of semiconductor layers 139 and a plurality of sacrificial semiconductor layers 141 interleaved with each other. The semiconductor layers 139 will be patterned to form stacks of channels 106. The semiconductor layers 141 will be patterned to form sacrificial semiconductor nanostructures 142 between channels 106. The sacrificial semiconductor nanostructures 142 will eventually be removed and the gate metals 108 will be formed in their place.

In one embodiment, the semiconductor layers 139 includes silicon or other materials described in relation to the channels in FIG. 1, though other semiconductor materials can be utilized without departing from the scope of the present disclosure. In one embodiment, the sacrificial semiconductor layers 141 include a semiconductor material different than the semiconductor material of the layers 139. This enables the sacrificial semiconductor layers 141 to be selectively etched with respect to the semiconductor layers 139. In an example in which the semiconductor layers 139 include silicon, the sacrificial semiconductor layers 141 may include silicon germanium.

The integrated circuit 100 includes a plurality of dummy gate structures 140 on the stack 138. The position of the dummy gate structures 140 corresponds to a position below which a stack of channels 106 will be formed when the stack 138 is patterned, as shown in FIG. 2B. The dummy gate structures 140 are placed on locations at which gate electrodes of the transistors 104 will be placed.

The dummy gate structures 140 each include a layer of polysilicon 144. The layer of polysilicon 144 can have a thickness between 20 nm and 100 nm. The layer of polysilicon 144 can be deposited by an epitaxial growth, a CVD process, a physical vapor deposition (PVD) process, or an ALD process. Other thicknesses and deposition processes can be used for depositing the layer polysilicon 144 without departing from the scope of the present disclosure.

A spacer layer 124 has been deposited on the polysilicon layer 144 and the dielectric layers 146 and 148. The spacer layer can include silicon nitride, SiOCN, or other suitable dielectric layers. The spacer layer 124 can be deposited by CVD, PVD, ALD, or other suitable processes. The spacer layer 124 can have a thickness between 2 nm and 10 nm. The spacer layer 124 can have other materials, deposition processes, and thicknesses without departing from the scope of the present disclosure.

In FIG. 2B, trenches 150 have been formed in the stack 138. The dummy gate structures 140 are utilized as a pattern for forming the trenches 150. The trenches 150 may correspond to source/drain trenches, as source/drain regions 110 will be formed therein. Formation of the trenches 150 defines stacks of individual channels 106 from the semiconductor layers 139. Formation of the trenches 150 also defines stacks of sacrificial semiconductor nanostructures 142. The trenches 150 extends into the substrate 102 below the lowest sacrificial semiconductor nanostructures 142. As will be set forth in more detail below, source/drain epitaxial structures 118 will be formed at the bottom of the trenches 150.

In FIG. 2C, a recess step has been performed to recess the sacrificial semiconductor nanostructures 142. The recessing process removes outer portions of the sacrificial semiconductor nanostructures 142 without entirely removing the sacrificial semiconductor nanostructures 142. The recessing process can be performed with an isotropic etch that selectively etches the material of the sacrificial semiconductor nanostructures 142 with respect to the materials of the semiconductor channels 106 and the substrate 102. The isotropic etching process can include a timed etching process. The duration of the etching process is selected to remove only a portion of the sacrificial semiconductor nanostructures 142 without entirely removing the sacrificial semiconductor nanostructures 142.

In FIG. 2D, dielectric spacers 114 have been deposited between the exposed portions of the semiconductor channels 106. In particular, the dielectric spacers 114 are formed at the locations where the sacrificial semiconductor nanostructures 142 have been recessed. The dielectric spacers 114 can be deposited by an ALD process, a CVD process, or other suitable processes. In one example, the dielectric spacers 114 include silicon nitride. Other materials and deposition processes can be utilized for the dielectric spacers 114 without departing from the scope of the present disclosure.

FIG. 2E illustrates the location of both the transistor 104a (e.g., P-type) and the transistor 104b (e.g., N-type). In FIG. 2E, epitaxial semiconductor layers 119 of source/drain epitaxial structures 118 have been formed on the bottom of the trenches 150 at both the transistor 104a and 104b. The epitaxial semiconductor layers 119 can be formed with an epitaxial growth process from the substrate 102. In an example in which the substrate 102 includes silicon, the semiconductor layer 119 may include silicon germanium with a concentration less than 25%. In some embodiments, the epitaxial semiconductor layers 119 can include intrinsic semiconductor material (undoped).

At the stage of processing shown in FIG. 2E, the top surfaces of the semiconductor layers 119 are substantially even with or slightly higher than a bottom surface of the lowest sacrificial semiconductor nanostructure 142. The top surfaces of the semiconductor layers 119 is higher than the bottom surface of the lowest inner spacer 114.

In FIG. 2F, a mask 152 has been formed in the trenches 150 of the transistor 104b, in accordance with some embodiments. The mask 152 is not present at the transistor 104a. The mask 152 can include a conductive material such as titanium, aluminum, tungsten, or other conductive materials. The mask 152 can include a dielectric material such as silicon nitride, silicon oxynitride, silicon oxide, silicon carbide, silicon oxycarbide, silicon oxycarbonitride, or other suitable dielectric materials. The mask 152 can be deposited by ALD, PVD, CVD, or other processes. The mask 152 can be patterned using photolithography processes.

In some embodiments, an initial recessing process has been performed at the transistor 104a to recess the top surface of the semiconductor layers 119a. After the initial recessing, the top surface of the semiconductor layer 119a is slightly concave and is below a lowest surface of the lowest inner spacer 114. Because the mask 152 is present at the transistor 104b, the semiconductor layer 119b is not recessed.

In FIG. 2G, a further recessing process has been performed at the transistor 104a, in accordance with some embodiments. The further recessing process can be accomplished via an isotropic etching process that selectively etches the semiconductor material of the semiconductor layer 119 with respect to other exposed materials. The result is that the top surface of the semiconductor layer 119 is recessed by a dimension D1 below the bottom surface of the lowest sacrificial semiconductor nanostructure 142. The dimension D1 can be between 5 nm and 10 nm, though other values can be utilized without departing from the scope of the present disclosure. Furthermore, the recessing process has rendered the top surface of the semiconductor layer 119a highly concave.

Another result of the recessing process is a slight inward recessing of the channels 106a. While the etching process etches the semiconductor material of the semiconductor layer 119 at a higher rate than the semiconductor material of the channels 106, some etching of the semiconductor channels 106 still occurs. As can be seen, the channels 106a are recessed laterally by a dimension D2 with respect to an outer edge of the inner spacers 114 and the dielectric layer 124. The dimension D2 can have a value between 1 nm and 3 nm, though other values can be utilized without departing from the scope of the present disclosure. Due to the presence of the mask 152 at the transistor 104b, no recessing occurs at the transistor 104b in FIG. 2G.

In FIG. 2H, a series of epitaxial growth processes has been performed at the transistor 104a. A first epitaxial growth process forms the semiconductor layer 121a on the semiconductor layer 119a of the source/drain epitaxial structures 118a. The second epitaxial semiconductor layer 121a is in direct contact with the first epitaxial semiconductor layer 119a and with a portion of the substrate 102 above the first epitaxial semiconductor layer 119a. Indeed, the second epitaxial semiconductor layer 121a is epitaxially grown from the semiconductor layer 119a. The semiconductor layer 121a has a bottom surface in the shape of the recess in the substrate 102. The semiconductor layer 121a has a top surface with a concave shape.

In some embodiments, the epitaxial semiconductor layer 121a includes a different semiconductor material than the semiconductor layer 119a and the same semiconductor material as the substrate 102. In an example in which the substrate 102 includes silicon and the semiconductor layer 119a includes silicon germanium, the semiconductor layer 121a includes silicon. The difference in crystalline structure of the semiconductor layer 121a can assist in imparting a beneficial strain or stress to the source/drain region 110a and to the channels 106a. In some embodiments, the epitaxial semiconductor layer 121a is doped with P-type dopant atoms in situ during the epitaxial growth process. The P-type dopant atoms can include boron or other dopant species.

In some embodiments, the epitaxial growth process that forms the semiconductor layer 121a of the source/drain bottom epitaxial structure 118a also results in formation of the source/drain layers 113a. The semiconductor layers 113a are grown epitaxially from the channels 106a. The semiconductor layers 113a can include silicon doped in situ with P-type dopant atoms, though other materials and processes can be utilized without departing from the scope of the present disclosure. The semiconductor layers 113a grow from the recesses that were formed in the channels 106a.

In some embodiments, another epitaxial growth process is utilized to growth the epitaxial semiconductor layer 122a of source/drain bottom epitaxial structure 118a. The epitaxial semiconductor layer 122a is on the epitaxial semiconductor layer 121a. The epitaxial semiconductor layer 122a may contact a portion of the lowest inner spacers 114. In some embodiments, the top surface of the epitaxial semiconductor layer 122a is convex in that the central portion is higher than a lateral end portions.

In some embodiments, the semiconductor layer 122a includes a different semiconductor material than the semiconductor layer 121a. In an example in which the layer 119a includes silicon germanium and the layer 121a include silicon, the semiconductor layer 122a include silicon germanium. The concentration of germanium of the semiconductor layer 122a is less than 25%, though other concentrations can be utilized without departing from the scope of the present disclosure. The mismatch in semiconductor materials can assist in imparting a beneficial strain or stress to the channel region 110a and to the channels 106a. The semiconductor layer 122a can be doped with P-type dopant atoms, such as boron, or other suitable dopant species.

In some embodiments, the semiconductor layers 115a are grown in the same epitaxial growth process as the semiconductor layer 122a. Accordingly, the semiconductor layers 115a have a same material as the semiconductor layer 122a. The epitaxial semiconductor layers 115a are grown epitaxially from the epitaxial semiconductor layers 113a.

A subsequent epitaxial growth process can be performed to form the semiconductor layer 112a. The semiconductor layer 112a corresponds to a bulk source/drain region that fills the remaining areas of the source/drain trenches and gross to a height above the highest channel 106 a. The semiconductor layer 112a includes a different semiconductor material than the source/drain layers 115a and 122a. In an example in which the semiconductor layers 115a and 122a include silicon germanium with a germanium concentration less than 25%, the semiconductor layer 112a can include silicon germanium with a concentration greater than 25% and doped in situ with P-type dopant species. Other processes and materials can be utilized without departing from the scope of the present disclosure.

In FIG. 2H, formation of the source/drain regions 110a is complete. No epitaxial growth has occurred at the transistor 104b due to the presence of the mask 152.

In FIG. 2I, the mask 152 has been removed from the transistor 104b, in accordance with some embodiments. After removal of the mask 152, the dielectric isolation structures 120b have been formed on the top surface of the epitaxial semiconductor regions semiconductor layers 119b of the source/drain bottom epitaxial structure 118b. The dielectric isolation structures 120b can be deposited by CVD, ALD, PVD, or other processes, and subsequently patterned.

In some embodiments, the dielectric isolation structures 120b may include SiN, SiON, SiOCN, SiOC, SiCN, SiO, AlO, HfO, or other suitable dielectric materials. The dielectric isolation structure 120b may have a thickness between 1 nm and 15 nm. This thickness may be sufficiently thick to ensure substantially no leakage current, but not so thick as to adversely affect the potential thickness of a source/drain region that will be formed thereon. Other thicknesses and materials can be utilized for the dielectric isolation structures 120b without departing from the present disclosure.

The presence of the dielectric isolation structures 120b ensures that leakage currents will not flow from the source/drain regions 110b into the semiconductor substrate 102. This can greatly enhance the efficiency of the transistor 104b by substantially eliminating leakage currents. This reduces power consumption and heat generation.

In FIG. 2I, an epitaxial growth process has been performed to form the epitaxial semiconductor layers 115b of the source/drain regions 110b. The semiconductor layers 115b can be grown epitaxially from the channels 106b. The semiconductor layers 115a can include silicon doped in situ with N-type dopant atoms, though other materials and processes can be utilized without departing from the scope of the present disclosure. In some embodiments, the semiconductor layers 115b can be doped with arsenic or phosphorus. The semiconductor layers 115b protrude complexly from the channels 106b.

In FIG. 2I, an epitaxial growth process has been performed to form a semiconductor layer 112b of the source/drain regions 110b. Semiconductor layer 112b can be grown epitaxially from the semiconductor layers 115b. The semiconductor layer 112b corresponds to a bulk source/drain region that fills the remaining areas of the source/drain trenches and gross to a height above the highest channel 106b. In some embodiments, the semiconductor layer 112b include silicon doped with N-type dopants species. In one example, the semiconductor layer 112b is doped with phosphorus, while the semiconductor layer 115b is doped with arsenic.

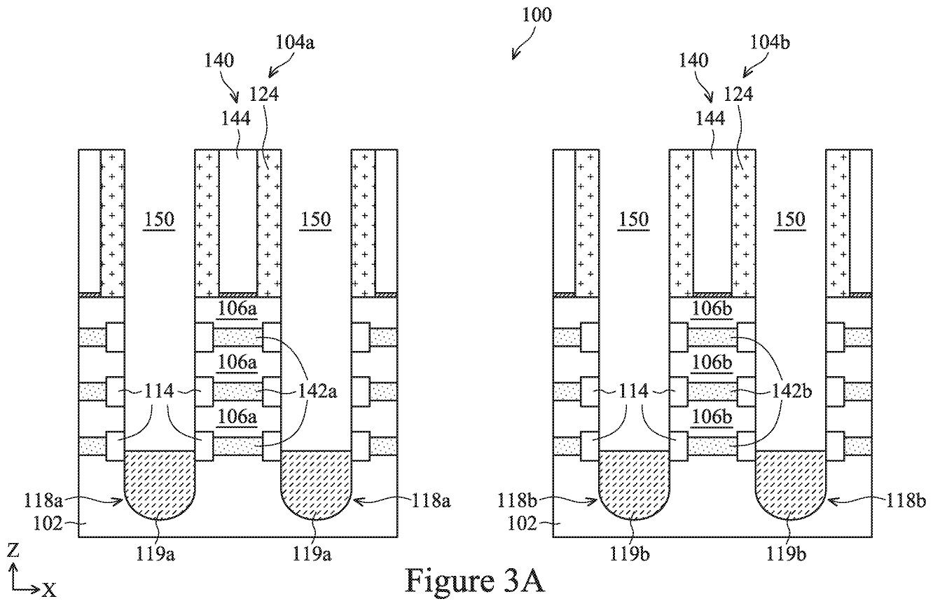

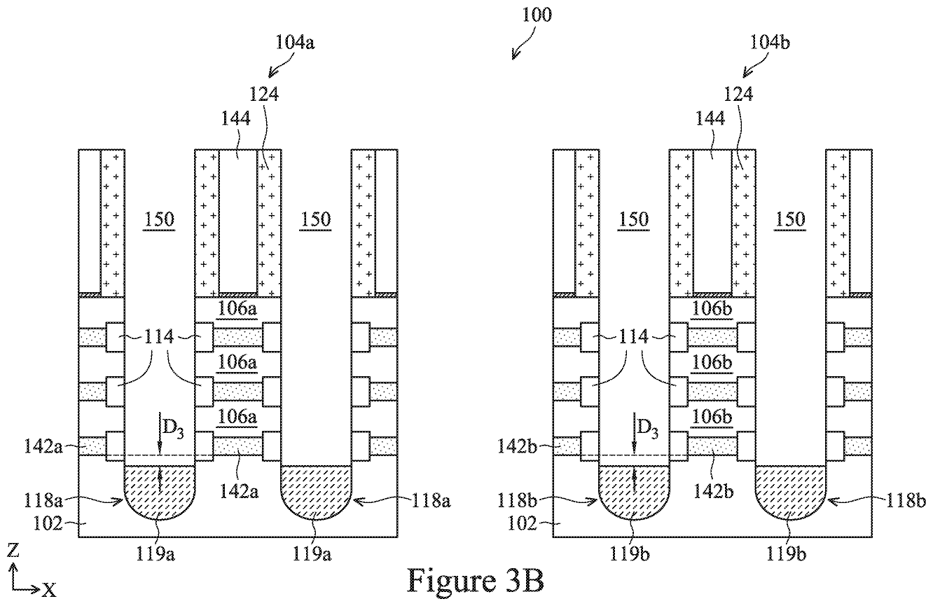

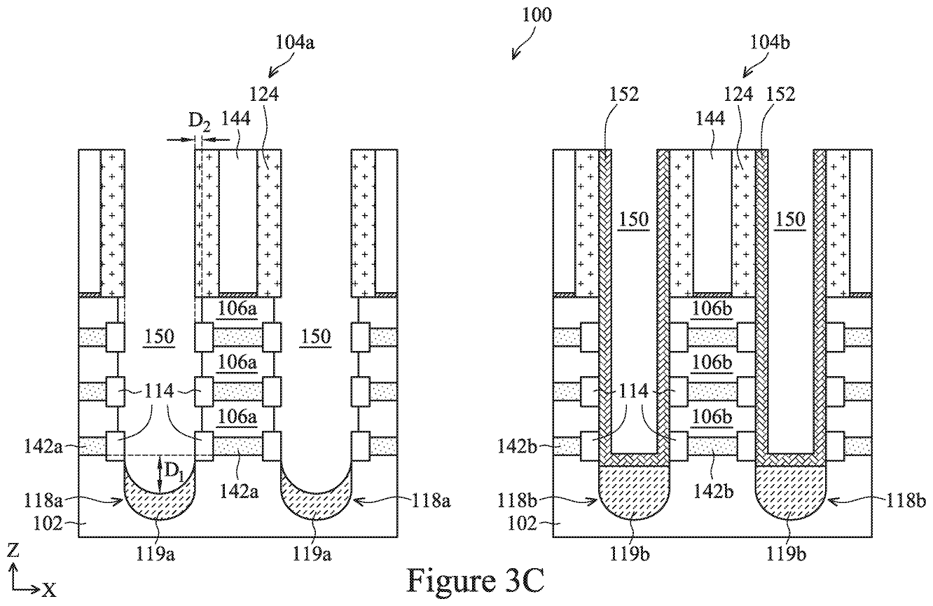

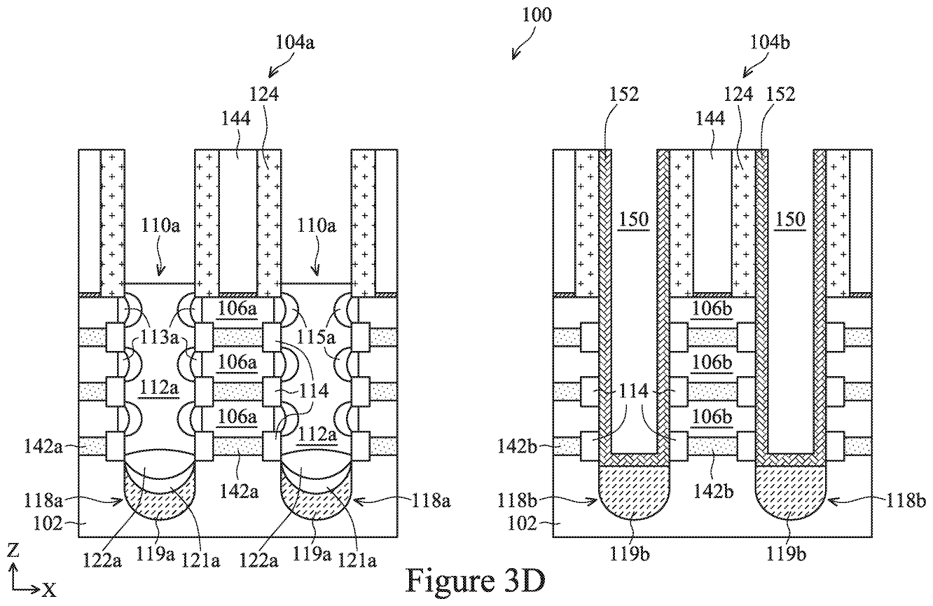

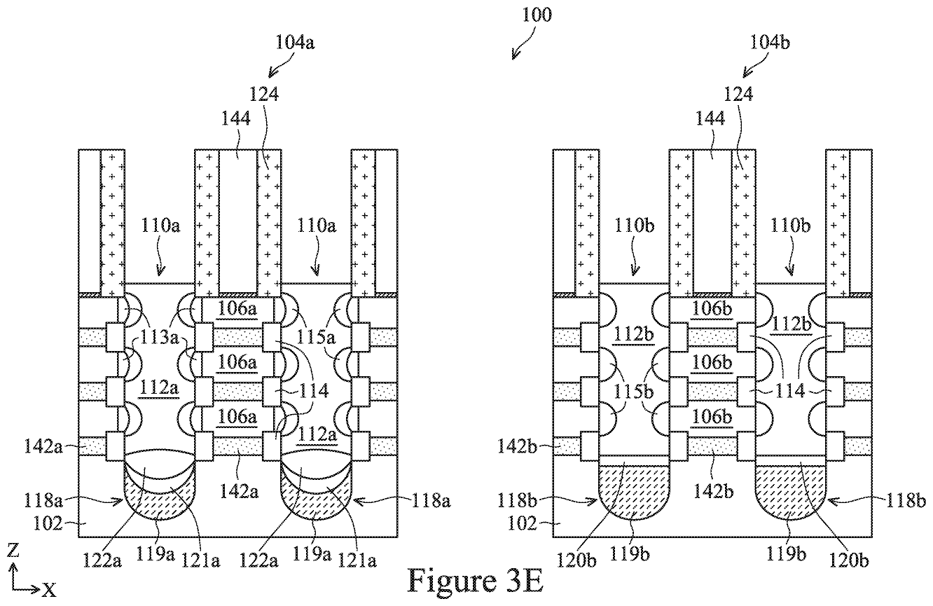

FIGS. 3A-3E are cross-sectional views of an integrated circuit 100 at various stages of processing, in accordance with some embodiments. In FIG. 3A, the integrated circuit 100 is substantially a same stage of processing as is shown in FIG. 2E.

In FIG. 3B, an initial recessing process has been performed at the transistor 104a and 104b to recess the top surface of the semiconductor layers 119. After the initial recessing, the top surface of the semiconductor layer 119 is slightly concave and is below a lowest surface of the lowest inner spacer 114. The top surface of the semiconductor layer 119 is lower than a bottom surface of the lowest sacrificial semiconductor nanostructure 142 by a dimension D3. The dimension D3 can have a value between 1 nm and 5 nm, though other dimensions can be utilized without departing from the scope of the present disclosure.

In FIG. 3C, a mask 152 has been formed in the trenches 150 of the transistor 104b, in accordance with some embodiments. The mask 152 is not present at the transistor 104a. The mask 152 can include a conductive material such as titanium, aluminum, tungsten, or other conductive materials. The mask 152 can include a dielectric material such as silicon nitride, silicon oxynitride, silicon oxide, silicon carbide, silicon oxycarbide, silicon oxycarbonitride, or other suitable dielectric materials. The mask 152 can be deposited by ALD, PVD, CVD, or other processes. The mask 152 can be patterned using photolithography processes.

In FIG. 3C, a further recessing process has been performed at the transistor 104a, in accordance with some embodiments. The further recessing process can be accomplished via an isotropic etching process that selectively etches the semiconductor material of the semiconductor layer 119a with respect to other exposed materials. The result is that the top surface of the semiconductor layer 119a is recessed by a dimension D1 below the bottom surface of the lowest sacrificial semiconductor nanostructure 142. The dimension D1 can be between 5 nm and 10 nm, though other values can be utilized without departing from the scope of the present disclosure. Furthermore, the recessing process has rendered the top surface of the semiconductor layer 119a highly concave.

Another result of the recessing process is a slight inward recessing of the channels 106a. While the etching process etches the semiconductor material of the semiconductor layer 119 at a higher rate than the semiconductor material of the channels 106, some etching of the semiconductor channels 106 still occurs. As can be seen, the channels 106a are recessed laterally by a dimension D2 with respect to an outer edge of the inner spacers 114 and the dielectric layer 124. The dimension D2 can have a value between 1 nm and 3 nm, though other values can be utilized without departing from the scope of the present disclosure. Due to the presence of the mask 152 at the transistor 104b, no recessing occurs at the transistor 104b in FIG. 3C.

In FIG. 3D, a series of epitaxial growth processes has been performed at the transistor 104a. The series of epitaxial growth processes forms the semiconductor layers 121a, 122a, 113a, 115a, and 112a, substantially as described in relation to FIG. 2H. In FIG. 3D, formation of the source/drain regions 110a is complete. No epitaxial growth has occurred at the transistor 104b due to the presence of the mask 152.

In FIG. 3E, the mask 152 has been removed from the transistor 104b, in accordance with some embodiments. After removal of the mask 152, the dielectric isolation structures 120b and the semiconductor layers 112b and 115b of the source/drain regions 110b have been formed substantially as described in relation to FIG. 2I. One difference from the structure of FIG. 2 I is that the top surface of the semiconductor layer 119b is below a lowest surface of the lowest inner spacer 114. Additionally, a bottom surface of the isolation structures 120b is lower than a lowest surface of the lowest inner spacers 114, while a top surface of the isolation structures 120b is above a lower surface of the lowest inner spacers 114. In FIG. 3D, formation of the source/drain regions 110b is complete.

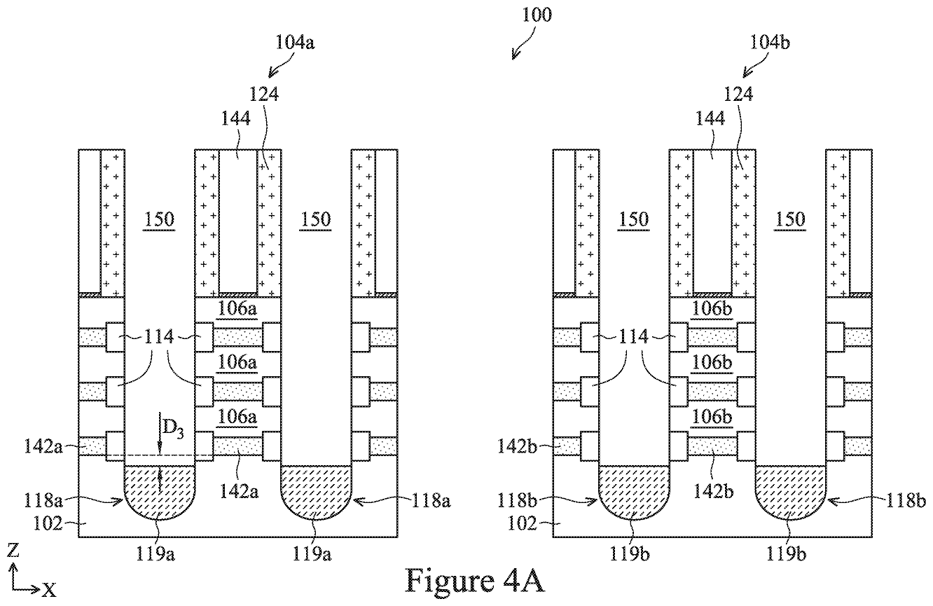

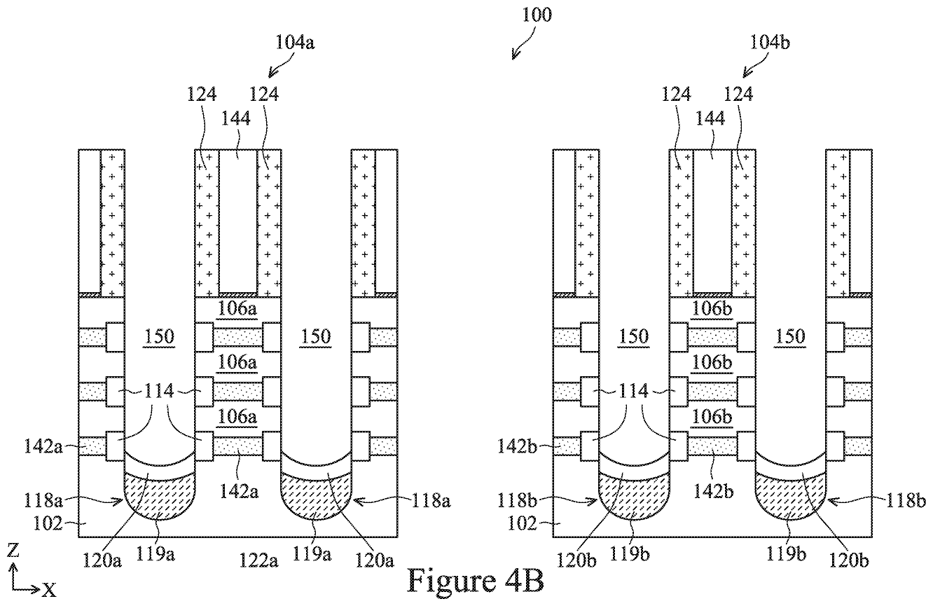

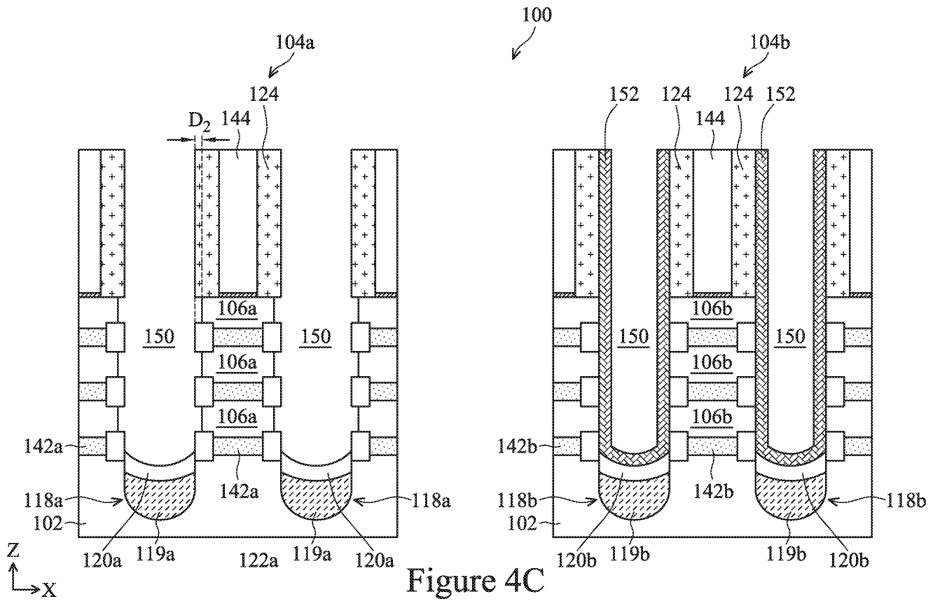

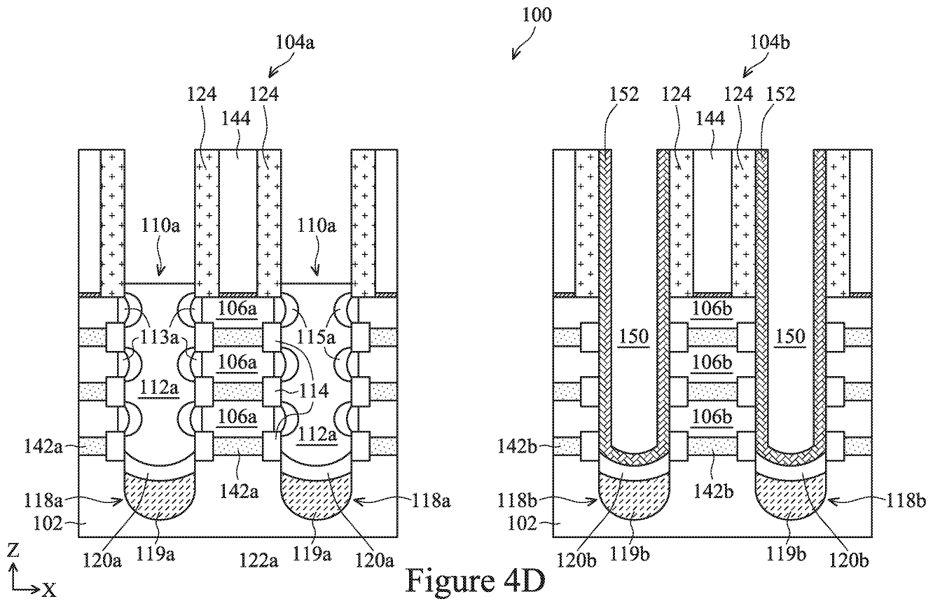

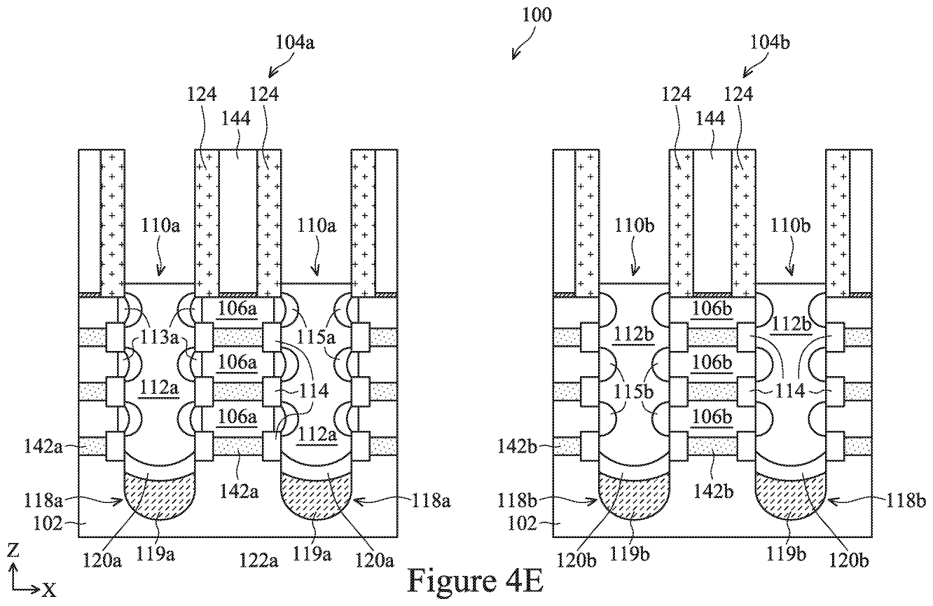

FIGS. 4A-4E are cross-sectional views of an integrated circuit 100 at various stages of processing, in accordance with some embodiments. In FIG. 4A, the integrated circuit 100 is substantially a same stage of processing as is shown in FIG. 3B.

In FIG. 4B, a recessing process has been performed at both of the transistors 104, in accordance with some embodiments. The further recessing process can be accomplished via an isotropic etching process that selectively etches the semiconductor material of the semiconductor layer 119 with respect to other exposed materials. The result is that the top surface of the semiconductor layer 119 is recessed below the bottom surface of the lowest sacrificial semiconductor nanostructure 142. Furthermore, the recessing process has rendered the top surface of the semiconductor layer 119a highly concave. Though not shown in FIG. 4B, in some embodiments the channels 106 of both transistors 104 may be inwardly recessed as shown for the channels 106a of FIG. 3C.

In FIG. 4B, the dielectric isolation structures 120 have been formed on the semiconductor layers 119 at both transistors 104, in accordance with some embodiments. The materials, deposition processes, and thicknesses of the dielectric isolation structures 120 can be substantially the same as described previously. One difference is that due to the highly concave top surface of the semiconductor layers 119, the dielectric isolation structures 120 are also concave in FIG. 4B.

In FIG. 4C, a mask 152 has been formed in the trenches 150 of the transistor 104b, in accordance with some embodiments. The mask 152 is not present at the transistor 104a. FIG. 4C shows recesses in the channels 106a. This can be accomplished via an additional isotropic etching process. Alternatively, as described previously, the etching process described in relation to FIG. 4B can cause recesses to form in the channels 1068 of both transistors 104.

In FIG. 4D, a series of epitaxial growth processes has been performed at the transistor 104a. The series of epitaxial growth processes forms the semiconductor layers 113a, 115a, and 112a, substantially as described in relation to FIG. 2H. In FIG. 4D, formation of the source/drain regions 110a is complete. No epitaxial growth has occurred at the transistor 104b due to the presence of the mask 152.

In FIG. 4E, the mask 152 has been removed from the transistor 104b, in accordance with some embodiments. After removal of the mask 152, the semiconductor layers 112b and 115b of the source/drain regions 110b have been formed substantially as described in relation to FIG. 2I. One difference from the structure of FIG. 2 I is that the bottom surface of the semiconductor layer 112b is convex in accordance with the shape of the dielectric isolation structures 120b. The bottom surface of the semiconductor layer 112 a is also convex in the same manner.

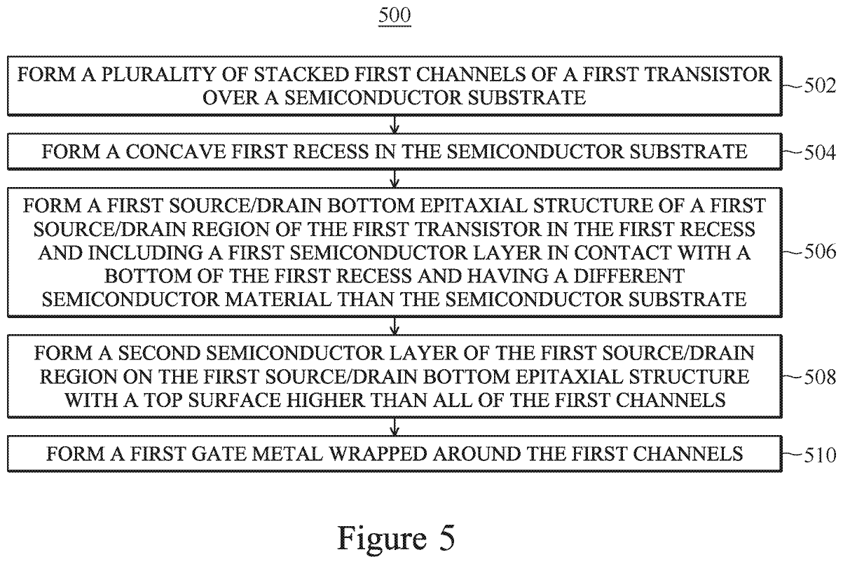

FIG. 5 is a flow diagram of a method 500 for forming an integrated circuit, in accordance with some embodiments. The method 500 can utilize processes, structures, and components described in relation to FIGS. 1-4E. At 502, the method 500 includes forming a plurality of stacked first channels of a first transistor over a semiconductor substrate. One example of a semiconductor substrate is the semiconductor substrate 102 of FIG. 1. One example of a first transistor is the first transistor 104a of FIG. 1. One example of first channels are the first channels 106a of FIG. 1. At 504, the method 500 includes forming a concave first recess in the semiconductor substrate. One example of a first recess is the bottom of the trench 150 of FIG. 2B. At 506, the method 500 includes forming a first source/drain bottom epitaxial structure of a first source/drain region of the first transistor in the first recess and including a first semiconductor layer in contact with a bottom of the first recess and having a different semiconductor material than the semiconductor substrate. One example of a first/source drain region is the source/drain region 110a of FIG. 1. One example of a source/drain bottom epitaxial structure is the source/drain bottom epitaxial structure 118a of FIG. 1. One example of a first semiconductor layer is the semiconductor layer 119a of FIG. 1. At 508, the method 500 includes forming a second semiconductor layer of the first source/drain region on the first source/drain bottom epitaxial structure with a top surface higher than all of the first channels. One example of a second semiconductor layer is the semiconductor layer 112a of FIG. 1. At 510, the method 500 includes forming a first gate metal wrapped around the first channels. One example of a first gate metal is the gate metal 108a of FIG. 1.

Embodiments of the present disclosure provide an integrated circuit with nanostructure transistors. Each nanostructure transistor includes a plurality of stacked channels. The stacked channels extend between source/drain regions. Embodiments of the present disclosure provide source/drain regions with bottom epitaxial structures extending lower than a lowest channel. The bottom epitaxial structures include semiconductor materials with different compositions than other higher portions of the source/drain regions. Furthermore, N-channel transistors and P-channel transistors may have different types of bottom epitaxial structures with different numbers of layers and different shapes of layers. The result is that stress or strain can be imparted to the source/drain regions and channels in a manner selected to improve DC performance of the transistors. This results in transistors with improved characteristics, integrated circuits with improved characteristics, and electronic devices with improved characteristics. Furthermore, the function and reliability of transistors is improved in such a way that wafer yields are improved, resulting in fewer scrapped wafers.

In some embodiments, a method includes forming a plurality of stacked first channels of a first transistor over a semiconductor substrate and forming a concave first recess in the semiconductor substrate. The method includes forming a first source/drain bottom epitaxial structure of a first source/drain region of the first transistor in the first recess and including a first semiconductor layer in contact with a bottom of the first recess and having a different semiconductor material than the semiconductor substrate. The method includes forming a second semiconductor layer of the first source/drain region on the first source/drain bottom epitaxial structure with a top surface higher than all of the first channels and forming a first gate metal wrapped around the first channels.

In some embodiments, an integrated circuit includes a semiconductor substrate, a first recess in the semiconductor substrate, and a first transistor. The first transistor includes a plurality of stacked first channels, a bottom of the first recess being lower than all of the first channels, and a first source/drain. The first source/drain region includes a first semiconductor layer in contact with the bottom of the first recess and having a concave top surface lower than all of the first channels and a different semiconductor material than the semiconductor substrate. The first source/drain region includes a second semiconductor layer having a bottom surface lower than all of the channels and a top surface higher than all of the first channels.

In some embodiments, an integrated circuit includes a semiconductor substrate, a first recess in the semiconductor substrate, and a first transistor of a first conductivity type. The first transistor includes a plurality of stacked first channels, a first gate metal wrapped around the first channels, and a first source/drain region. The first source/drain region includes a first semiconductor layer on the bottom of the first recess and having a top surface below a bottom of the first gate metal and of a different semiconductor material than the semiconductor substrate. The first source/drain region includes a dielectric isolation region having a bottom surface on the top surface of the first semiconductor layer and lower than a bottom of the first gate metal.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a plurality of stacked first channels of a first transistor over a semiconductor substrate by forming a first source/drain trench through a plurality of semiconductor layers and extending into the substrate;
depositing a first source/drain bottom epitaxial structure of a first source/drain region of the first transistor in the first source/drain trench and including a first semiconductor layer in contact with a bottom of the source/drain trench and having a different semiconductor material than the semiconductor substrate;
recessing a top surface of the first semiconductor epitaxial structure to a level lower than a top surface of the substrate; and
depositing a second semiconductor layer of the first source/drain region on the first source/drain bottom epitaxial structure.

2. The method of claim 1, wherein the semiconductor substrate is silicon and the silicon germanium.

3. The method of claim 1, further comprising forming a third semiconductor layer of the first source/drain bottom epitaxial region on the first semiconductor layer and having a different material than the first semiconductor layer and a top surface lower than a bottom of a gate metal wrapped around the first channels.

4. The method of claim 3, wherein the third semiconductor layer is a same material as the first semiconductor layer.

5. The method of claim 4, comprising forming a fourth semiconductor layer of the first source/drain bottom epitaxial region in the first recess on the third semiconductor layer.

6. The method of claim 5, wherein the fourth semiconductor layer has a convex bottom surface lower than the bottom of the first gate metal and a convex top surface higher than the bottom of the gate metal.

7. The method of claim 4, wherein the first semiconductor layer is silicon germanium with a first concentration of germanium, the second semiconductor layer is silicon germanium with a second concentration of germanium less than the first concentration, and the fourth semiconductor layer is silicon germanium with a third concentration of germanium greater than the second concentration of germanium.

8. The method of claim 4, further comprising forming a fifth semiconductor layer of the first source/drain region by growing the fifth semiconductor layer from the first channels in a same epitaxial growth process as the fourth semiconductor layer, wherein the fifth semiconductor layer does not contact the fourth semiconductor layer.

9. The method of claim 8, further comprising epitaxially growing the second semiconductor layer from the fourth semiconductor layer and the fifth semiconductor layer.

10. The method of claim 1, further comprising:
forming a plurality of stacked second channels of a second transistor over the semiconductor substrate;
forming a second source/drain trench in the substrate;
forming a second source/drain bottom epitaxial structure of a second source/drain region of the second transistor in the second source/drain trench and including a third semiconductor layer in contact with a bottom of the second source/drain trench and having the same semiconductor material as the first semiconductor layer;
forming a dielectric isolation structure on the third semiconductor layer at the second recess, a top surface of the dielectric isolation structure being lower than all of the second channels; and
forming a fourth semiconductor layer of the second source/drain region on the dielectric isolation structure with a top surface higher than all of the second channels.

11. The method of claim 1, wherein the first transistor is a P-type transistor and the second transistor is an N-type transistor.

12. A method, comprising:
defining a plurality of first stacked channels by forming a first trench through a plurality of semiconductor layers and into a semiconductor substrate, a bottom of the first trench being lower than all of the first channels;
depositing a first semiconductor layer of a first source/drain region in contact with the bottom of the first trench and having a concave top surface lower than all of the first channels and a different semiconductor material than the semiconductor substrate; and
depositing a second semiconductor layer of the first source/drain region having a bottom surface lower than all of the first channels and a top surface higher than all of the first channels.

13. The method of claim 12, further comprising:
defining a plurality of second stacked channels by forming a second trench through the plurality of semiconductor layers and into the semiconductor substrate, a bottom of the second trench being lower than all of the second channels;
depositing a third semiconductor layer of a second source/drain region in contact with the bottom of the second trench and having a top surface lower than all of the second channels and a same semiconductor material as the first semiconductor layer;
depositing a first dielectric isolation region on the third semiconductor layer in the second trench and having a top surface lower than all of the second channels; and
depositing a fourth semiconductor layer of the second source/drain region on the first dielectric isolation region and having a top surface higher than all of the second channels.

14. The method of claim 13, wherein the first source/drain region includes a second dielectric isolation region on the first semiconductor layer in the first trench and having a top surface lower than all of the first channels.

15. The method of claim 14, wherein the top surface of the first dielectric isolation region is concave and the top surface of the second dielectric isolation region is concave.

16. The method of claim 13, further comprising forming a plurality of first inner spacers each between a respective pair of the first channels and abutting the second semiconductor layer, wherein the first channels are laterally recessed with respect to the first inner spacers.

17. The method of claim 16, further comprising forming a plurality of second inner spacers each between a respective pair of the first channels and abutting the fourth semiconductor layer, wherein vertical sidewalls of the second channels are substantially coplanar with vertical sidewalls of the second inner spacers.

18. An integrated circuit, comprising:
a semiconductor substrate;
a first trench in the semiconductor substrate; and
a first transistor of a first conductivity type and including:
a plurality of stacked first channels;
a first gate metal wrapped around the first channels; and
a first source/drain region including:
a first source/drain bottom epitaxial structure of a first source/drain region of the first transistor in the first trench and including a first semiconductor layer in contact with a bottom of the source/drain trench and having a different semiconductor material than the semiconductor substrate, wherein a top surface of the first semiconductor epitaxial structure is at a level lower than a top surface of the substrate; and
a second semiconductor layer of the first source/drain region on the first source/drain bottom epitaxial structure.

19. The integrated circuit of claim 18, wherein the first source/drain region includes a second semiconductor layer in contact with a top surface of the dielectric isolation region and having a top surface higher than all of the first channels.

20. The integrated circuit of claim 19, further comprising:
a second trench in the semiconductor substrate: and
a second transistor of a second conductivity type including:
a plurality of stacked second channels;
a second gate metal wrapped around the second channels; and
a second source/drain region including:
a third semiconductor layer on a bottom of the second trench;
a fourth semiconductor layer on the third semiconductor layer in the trench; and
a fifth semiconductor layer having a bottom surface in contact with the fourth semiconductor layer lower than all of the second channels and the top surface higher than all of the second channels.
